(19) United States
(12) Patent Application Publication
(10) Pub. No.: US 2025/0132139 A1
(43) Pub. Date: Apr. 24, 2025

(54) PLASMA PROCESS CONTROL USING FLUORINE RADICAL CONCENTRATIONS

(71) Applicant: Applied Materials, Inc., Santa Clara, CA (US)

(72) Inventors: Hari Ponnekanti, Santa Clara, CA (US); Irfan Arshad Malik, Santa Clara, CA (US)

(21) Appl. No.: 18/896,276

(22) Filed: Sep. 25, 2024

Related U.S. Application Data
(60) Provisional application No. 63/591,740, filed on Oct. 19, 2023.

(51) Int. Cl. H01J 37/32

(52) U.S. Cl. CPC H01J 37/3299; H01J 37/32357; H01J 37/32449; H01J 37/32844; H01J 2237/24585

(57) ABSTRACT

A system includes a remote plasma source, a processing chamber comprising a radical sensor, and a controller. The radical sensor is configured to measure the concentration of fluorine radicals in the processing chamber. The controller is to adjust one or more settings of at least one of the remote plasma source or the processing chamber based on the measured concentration of fluorine radicals in the processing chamber.

### RELATED APPLICATIONS

The present application claims the benefit under 35 U.S.C. § 119 (e) of U.S. Provisional Patent Application No. 63/591,740 filed Oct. 19, 2023, which is incorporated by reference herein.

### TECHNICAL FIELD

The instant specification relates to gas measurement and filtration, more particularly, it relates to measurement of radicals and/or ions in a gas flow.

### BACKGROUND

Many processes, such as processes for forming semiconductors, photovoltaics, displays, etc., use one or more gases to deposit layers, etch layers, clean substrates, and so on. For some processes a plasma is formed and used during deposition, etching, cleaning, etc. Currently, the gases used to generate radicals for these processes (e.g. NF₃, F₂, etc.) pose potential environmental hazard and can result in excessive wear of processing equipment. Strategies to measure, filter, and recycle these gases in manufacturing processes are currently underdeveloped.

In semiconductor processing, radical species are often used for various processing operations in a chamber. For example, a radical species, such as atomic fluorine, may be used in an etching or a chamber cleaning process. Radical species can be formed by various processes. One process to generate radical species is to use a plasma. For example, a fluorine containing gas is flowed into the chamber, and the plasma breaks the compound into elemental fluorine. Radical species are highly chemically reactive.

Process control of radical species is difficult. This is due, in part, to the highly reactive nature of the radical species. The radical species react whenever the radical species contacts any surface or other compound. Even if the surface does not react with the radical species, it still may serve as a site for recombination of the radicals with each other thus converting the species to other compounds. This reactivity encourages chamber processes (e.g. etching, deposition, etc.) to occur on process chamber surfaces resulting in excess wear or processing equipment. Conventionally, to mitigate these processes chamber cleaning is conducted that remove or prevent processing gases from being exposed to processing equipment for extended periods of time. However, these cleaning processes can range from 25 to 70 percent of operation time of process chambers in extreme cases.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a system includes a remote plasma source. The system further includes a processing chamber that includes a radical sensor that may be configured to measure the concentration of fluorine radicals in the processing chamber. The system further includes a controller that nay adjust one or more settings of at least one of the remote plasma source or the processing chamber based on the measured concentration of fluorine radicals in the processing chamber.

In one aspect of the disclosure, a method for performing a plasma-based process in a process chamber includes generating a plasma using a remote plasma source. The plasma further includes fluorine radicals. The method further includes monitoring a concentration of the fluorine radicals in the processing chamber using a radical sensor. The method further includes adjusting one or more settings of at least one of the remote plasma source or the processing chamber based on the measured concentration of the fluorine radicals in the processing chamber.

In one aspect of the disclosure, a computer readable medium that, when executed by a processing device, may cause the processing device to perform operations that include causing a plasma source to generate a plasma, the plasma including fluorine radicals. The operations further include receiving a measurement of a concentration of fluorine radicals in a processing chamber from a radical sensor and adjusting one or more settings of at least one of the remote plasma source or the processing chamber based at least in part on concentration of the fluorine radicals in the processing chamber.

### BRIEF DESCRIPTION OF THE DRAWINGS

The present disclosure is illustrated by way of example, and not by way of limitation in the figures of the accompanying drawings.

FIG. 1 is a sectional side view of a substrate processing system including a radical sensor, according to some embodiments.

FIG. 2A is a sectional side view of a radical sensor, according to some embodiments.

FIG. 2B is a back view of the radical sensor of FIG. 2A, according to some embodiments.

FIG. 2C is a front view of the radical sensor of FIG. 2A, according to some embodiments.

FIG. 2D is a sectional side view of the radical sensor of FIG. 2A with the addition of a charged grating or grid, according to some embodiments.

FIG. 2E shows an equivalent circuit for a piezoelectric resonator, according to some embodiments.

FIG. 2F shows an exploded view of one example of a radical sensor included in a sensor holder, according to some embodiments.

FIG. 2G shows an example sensor holder for a radical sensor, in accordance with some embodiments.

FIG. 2H shows an example sensor holder for a radical sensor, in accordance with some embodiments.

FIG. 3 is flow chart of one embodiment of a method for detecting and maintaining fluorine radical concentration via a plasma source.

FIG. 4 is a flow chart of one embodiment of a method for recycling processing gases to the processing chamber.

FIG. 5 is a block diagram illustrating a computer system, according to certain embodiments.

### DETAILED DESCRIPTION

A holistic approach to radical species concentration monitoring, process chamber cleaning, and input gas recycling is described in embodiments herein. Radical concentration sensing improves throughput and reduces waste of input gases. Tunable setting adjustment of remote plasma sources based on measured radical concentration and/or other measured properties increases throughput of process chamber operation. Compounds such as NF₃ have a higher environmental impact than gases such as CO₂, and reduction in waste of these compounds is beneficial for the environment (e.g., to minimize global warming). Radical sensing improves the efficiency of radical species used in manufacturing and chamber cleaning. Additionally, recirculation of F₂ and subsequently NF₃ reduces emissions from the described processes. In embodiments, a combination of a radical sensor, recirculation of process gases such as Fluorine and/or Argon to a plasma source for reuse, and detection of SiF₄ in an exhaust from a process chamber and/or of F₂ in exhaust recirculated back to a plasma source minimize an amount of time that process chamber cleaning is performed while minimizing amount of process gases (e.g., NF₃) used for the process chamber cleaning process.

Embodiments of the present disclosure relate to a manufacturing system that filters process chamber exhaust and recycles specific gases that can be used to generate additional radicals for manufacturing processes. Conventional plasma systems do not recirculate used gases or recycle used gases for generation of additional plasma and/or additional radicals. In embodiments described herein, a system recirculates at least some process gases back to a plasma source (e.g., to a remote plasma source) to reuse those gases. Such reuse of gases, such as F₂ and/or Argon reduces gas waste (e.g., of fluorine gas).

In some embodiments, a system includes a recirculation line for recirculating process gases back to a plasma source. However, some residual gases in an exhaust may have deleterious effects when recirculated back to a plasma source. Accordingly, in some embodiments a filter is disposed in a recirculation line to filter out some residual gases in an exhaust before the exhaust is recirculated back to a plasma source. In embodiments, the filter filters out gases such as SiF₄, HF, N₂, O₂, and/or other residual gases and/or byproducts, and does not filter out target gases that can be beneficial to reuse, such as F₂ and/or Ar. Accordingly, embodiments reduce gas waste for beneficial gases without exposing a plasma source to potentially harmful residual gases and/or byproducts in an exhaust.

In some embodiments, a sensor in an exhaust line from a process chamber measures an amount of silicon (e.g., SiF₄) in an exhaust during a clean process for the process chamber. The silicon may be a byproduct from one or more processes that deposits on walls of the process chamber. A clean operation of the process chamber may be complete when there is no detectable silicon left in the exhaust and/or when an amount of detected silicon in the exhaust falls below a threshold. The clean process may be stopped when the detected amount of silicon drops below a threshold and/or one or more settings for the clean operation may be adjusted when the amount of silicon in the exhaust reaches a threshold (e.g., falls below the threshold). For example, an amount of NF₃ provided to a plasma source may be reduced when the amount of silicon falls below a threshold to slow down the clean process. This may be performed to reduce the risk of exposing a cleaned chamber surface to corrosive fluorine radicals. Accordingly, a chamber life of a process chamber may be increased according to embodiments.

Embodiments discussed herein provide a system that can measure the amount of unreacted fluorine radical species coming out of a process chamber, filter the exhaust to recover these gases, and control the incorporation of recovered gases in a continuous production process.

Embodiments include specialized radical sensors that are configured to detect particular species of radicals. The radical sensors may be sensor devices that employ specialized coatings on surfaces of piezoelectric materials that oscillate at measurable resonant frequencies. The coating acts as a filter that filters out all molecules except for radicals of a target gas species. An example of such a piezoelectric material that may be used is quartz. For example, embodiments include a quartz crystal microbalance (QCM) with such a specialized coating on one surface of the QCM. The specialized coatings are designed for specific applications and are reactive to select molecular gas species used in those specific applications (without being reactive to other gas species). Examples of applications that the sensor devices may be designed for include etch operations, plasma assisted deposition processes (e.g., plasma assisted atomic layer deposition), plasma clean operations, and so on. The coating on the piezoelectric material changes mass based on a reaction of the coating to the select molecular gas species (e.g., to radicals of a particular molecule). The change in the coating's mass causes the resonant frequency at which the piezoelectric material oscillates to change. This change in the resonant frequency is measurable and may be used to determine the quantity of the molecular species that reacted with the coating. Accordingly, the sensor devices can directly measure specific molecular species of gases (e.g., fluorine radicals, hydrogen radicals, etc.). Such direct measurement of radicals enables closed loop control of plasma sources.

In an example, for a fluorine-based etch process or clean process, an etch rate (or rate of removal of a byproduct or coating being removed by a clean process) may strongly correlate to a concentration of fluorine radicals. By using a sensor device as described herein, the amount of fluorine radicals being flowed may be directly measured, and this measurement may be used to finely control the amount of radicals being output by a plasma source, such as a remote plasma source (RPS).

Incorporating a filtration system into the exhaust line of a processing chamber and directing filtered recycled materials (e.g., F₂ and/or Ar) to a plasma source mitigates waste of valuable materials. Sensor devices as described in embodiments account for the measurement and accurate use of recovered gases.

Without the ability to have a quantitative measurement of the concentration of radical species, closed loop control of the processing environment is not possible. Closed loop control refers to the use of quantitative measurements as a feedback signal to a controller in order to modify processing conditions in an ongoing process. For example, in the case of the measurement of radical species, a concentration of the radical species can be measured, and the measured value can be compared to a setpoint value. When the measured value is below the setpoint value, processing parameters may be changed to increase the generation rate and output concentration of radical species, or when the measured value is above the setpoint value, processing parameters may be changed to decrease the concentration of radical species. Additionally, these measurements can be used together with additional measurements of one or more species in an exhaust prior to filtration of the exhaust and/or after filtration of the exhaust to control a plasma process (e.g., a plasma clean process). As such, more stable and reproducible processes (e.g., clean processes) can be implemented in embodiments. Embodiments disclosed herein include a radical sensor that includes of a piezoelectric oscillator (e.g., a QCM) having a surface that is coated with a film that is reactive to a target radical species of a target gas or molecule, but that is not reactive to stable molecules of the gas or molecule or to radical or stable species of other gases or molecules that are flowed together with the target gas or molecule. The radical sensor may be used for closed loop control of plasma sources. The radical sensor may be in a process chamber and/or at a line between a remote plasma source and the process chamber. The radical sensor may be combined with a sensor in an exhaust line (e.g., for detecting SiF₄), a filter in the exhaust line, and/or an additional sensor in a recirculation line between the filter and the plasma source. The combination of these components may enable a controller to finely control a plasma process (e.g., a plasma clean process), determine when to stop the plasma process, and reuse process gases. Combined, these features may maximize the lift span of process chambers and their components, reduce an mount of process gases that are used, and maximize tool up-time for process chambers.

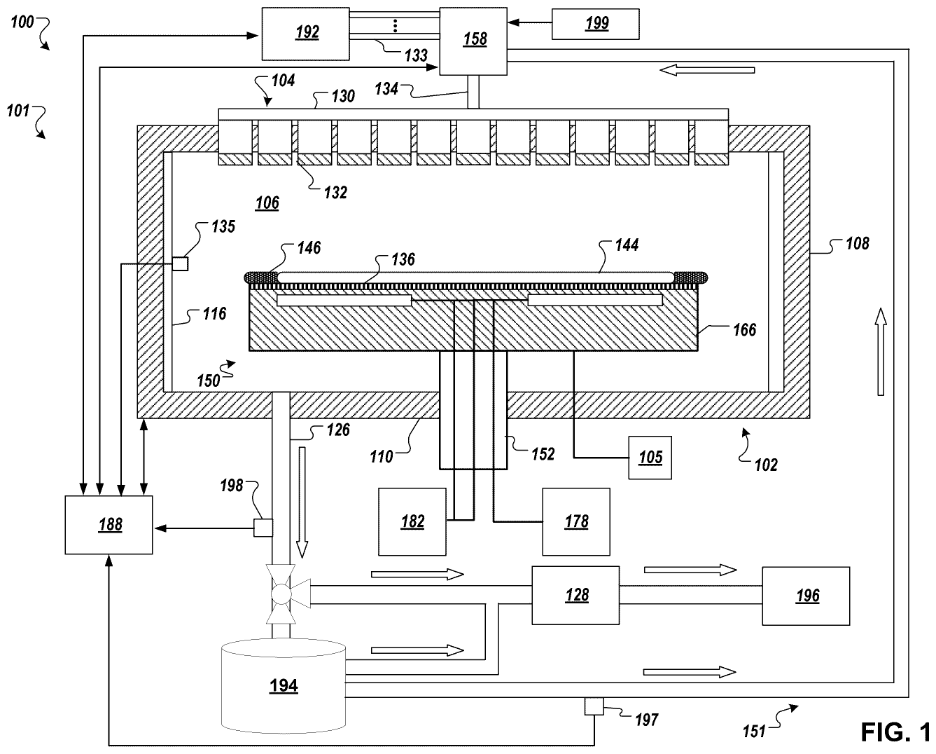

Referring now to the figures, FIG. 1 is a sectional view of a manufacturing system 100 that performs plasma-based processes in embodiments. The manufacturing system 100 may include a gas panel 192 connected to the plasma source 158 via one or more gas delivery lines. The gas delivery lines 133 may deliver gases such as process gases (e.g., chemical vapor deposition (CVD) precursors, ALD precursors, etch gases, cleaning gases (e.g., fluorine containing gases such as NF₃), carrier gases such as Ar, and so on. In embodiments, a different gas delivery line 133 may be used for each of the gases that may be delivered to plasma source 158.

In one embodiment, gas panel 192 controls the initial concentration of NF₃ and Ar gas that flows into the RPS 158. In embodiments, the gas panel 192 may be configured to deliver at least one gas to the RPS 158. In some embodiments, the at least one gas includes NF₃, F₂, C₂F₆, SF₆, SiCl₄, HBr, NF₃, CF₄, CHF₃, CH₂F₃, Cl₂ and SiF₄, Ar, N₂, He, or a combination thereof.

The manufacturing system may further include a processing chamber 101 coupled to plasma source 158 via one or more plasma delivery lines 134. A power source 199 may provide power to the plasma source 158. The plasma source 158 may generate a plasma, from one or more of the gases from gas panel 192, and may deliver the plasma (e.g., a gas containing the plasma) to the process chamber 101 via the one or more plasma delivery lines 134.

The processing chamber 101 may be, for example, a plasma etch reactor, a deposition chamber, etc. The processing chamber may be suitable for an etching operation, a deposition operation, a chamber cleaning operation, a plasma treatment operation, or any other type of operation typical of a semiconductor manufacturing facility. For example, the processing chamber may be configured for performing CVD, ALD, plasma-based etching, and so on.

In an embodiment, one or more substrates (e.g., wafers) 144 may be provided within the processing chamber 101. In an embodiment, processing chamber 101 may be maintained at a pressure suitable for a target operation. In a particular embodiment, the pressure may be between approximately 1 Torr and approximately 200 Torr. The processing chamber 101 is aged over time by the exposure the processing gases and materials. This aging results in retention of processing species or byproduct species that affect the effective concentration of active processing species in the processing chambers.

The processing chamber 101 and/or plasma source 158 may be connected to a controller 188, which may control processing of the plasma source 158, processing chamber 101 (e.g., by controlling set points, loading recipes, and so on), and/or the recirculation of recycled exhaust gases. A radical sensor 135 may be connected to the plasma delivery line(s) 133 and/or may be disposed within the processing chamber 101 to detect a concentration of radicals in a gas or plasma delivered by the plasma source 158 to processing chamber 101. In embodiments, the RPS 158 includes or is connected to power source 199 that is connected to deliver plasma-generating power to an energy conduit and/or to a gas distribution assembly that is further connected to a gas outlet configured to deliver excited gases to the processing chamber 101. In some embodiments, one or more settings of the RPS 158 include a power provided to the RPS 158 by the power source. Another setting for the RPS 158 may include a plasma frequency. Other settings that may affect a generated plasma (e.g., a concentration of fluorine radicals in a generated plasma) include a pressure in processing chamber 101, flow rates of one or more gases (e.g., process gasses such as NF₃), process time, and so on. In some embodiments, the excited gases provided from plasma source 158 to processing chamber 101 include fluorine radicals (e.g., F*). In some embodiments the gases provided from plasma source 158 to processing chamber 101 further include NF₃, F₂, NF, NF₂, or a combination thereof.

In some embodiments, the excited gases may include nitrogen-based radicals.

In embodiments, the fluorine and nitrogen-based radicals react with silicon based compounds in the processing chamber to form SiF₄ as a gaseous byproduct.

As indicated, in some embodiments the one or more settings of the remote plasma source 158 include a power output by the power source 199. In embodiments, controller 188 adjusts one or more settings of at least one of the RPS 158 or the processing chamber 101 based on the measured concentration of fluorine radicals in the processing chamber 101 measured by radical sensor 135. In some embodiments, the one or more settings of at least one of the RPS 158 or the processing chamber 101 includes at least one of a pressure within the processing chamber, a flow of excited gases to the processing chamber, a power of the RPS, or a frequency of the RPS.

In an embodiment, the manufacturing system 100 may comprise a radical sensor 135 that is fluidically coupled to the processing chamber 101 and/or to the plasma delivery line(s) 134. For example, a valve may be provided along a tube between the processing chamber 101 and the radical sensor 135. In an embodiment, the valve is a type of valve that allows for an unobstructed line of sight between the processing chamber 101 and the radical sensor 135. For example, the valve may be an isolation gate valve. An isolation gate valve may allow for a binary state of operation. That is, the valve may be open (i.e., 1) or closed (i.e., 0). When the valve is open, the line of sight is unobstructed. Alternately, another type of valve such as a needle valve may be used.

In embodiments, the radical sensor 135 comprises a piezoelectric substrate in a holder. The piezoelectric substrate is made to oscillate at a resonant frequency by applying an alternating current to the piezoelectric substrate. One or more surface of the piezoelectric substrate is coated by a film that is reactive to a narrow range of molecular species. In particular, the film is composed of a material that is reactive to a target molecular species of a particular target gas from among gases being used in a process. In one embodiment, the radical sensor comprises a QCM having at least one coated surface that is coated with a film that is selectively reactive to radicals of a particular gas. The radical sensor 135 is described in greater detail below with reference to the proceeding figures.

In some embodiments, the radical sensor 135 is a QCM sensor. The QCM sensor base may include a thin plate of quartz crystal that oscillates in the thickness-shear mode because such a QCM sensor base has high sensitivity to mass change on the crystal. The piezoelectric nature of quartz crystal allows the crystal to be driven into oscillation and with its resonant frequency measured by simple electrical means. In embodiments, the quartz crystal is precisely cut at certain angles with respect to its crystallographic axes. In embodiments, the quartz crystal is an AT-cut quartz crystal.

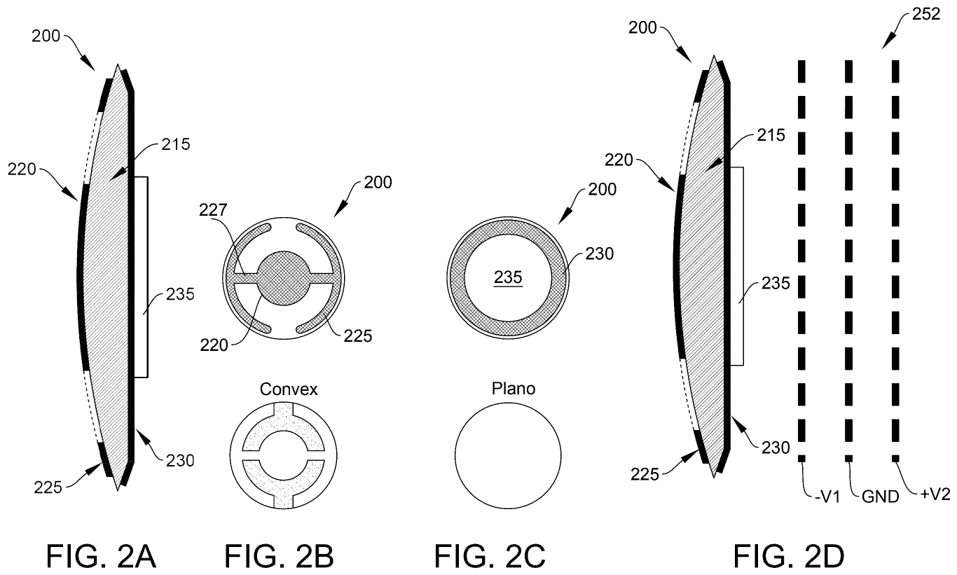

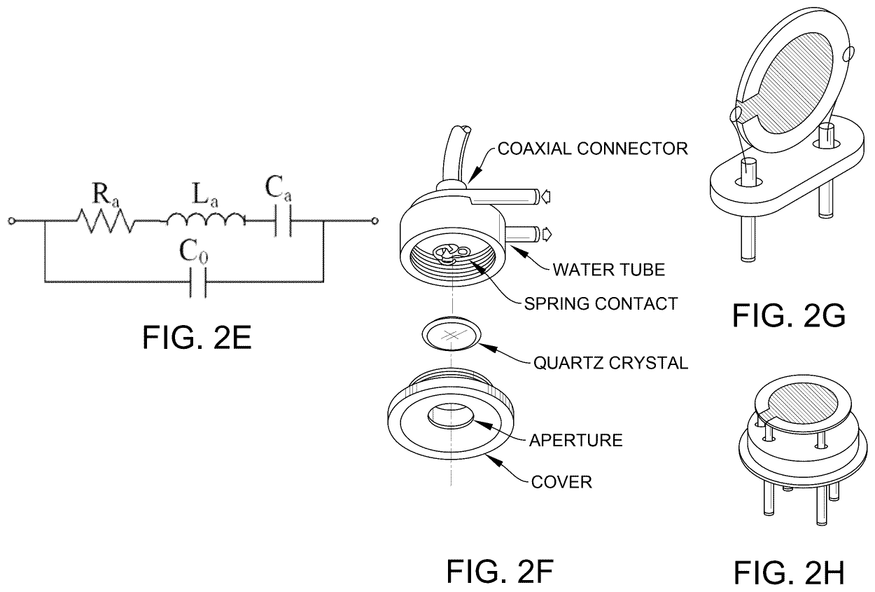

In some embodiments, radical sensor 135 is a QCM sensor having a coating that is reactant to fluorine radicals. In one embodiment, QCM sensor includes a silicon dioxide coating, or other coating that acts as a filter to react with fluorine radicals, as discussed in greater detail below with reference to FIGS. 2A-2H.

In one embodiment, in order to measure an amount of positively and/or negatively charged radicals, a pair of radical sensors may be used. A first radical sensor may include the charged gratings, and a second radical sensor may not include the charged gratings. All radicals of a target gas species may be detected by the second radical sensor, and only neutral radicals of the target gas species may be detected by the first radical sensor. A difference between the measurements of the two radical sensors may then be computed to determine an amount of the radicals detected by the second radical sensor that were attributable to charged radicals. The grating may be modified to only filter out positively charged molecules/ions or to only filter out negatively charged molecules. Accordingly, by combining two or more radical sensors, each with a different grating configuration (e.g., one not including any grating), an amount of positively charged radicals may be detected, an amount of negatively charged radicals may be detected, and/or an amount of neutral radicals may be detected.

In embodiments, the plasma source 158 is a remote plasma source (RPS) that generates plasma at a remote location and delivers the externally generated plasma to the processing chamber 101. Alternatively, the processing chamber 101 may include an integrated plasma source (not shown) that can generate plasma within the processing chamber. In either instance, the radical sensor 135 may be disposed within or connected to the processing chamber 101 rather than in or connected to the gas deliver lines 133 in embodiments.

Processing chamber 101 includes a substrate support assembly 150, according to some embodiments. Substrate support assembly 150 includes a puck 166 (e.g., may include an electrostatic chuck (ESC)). The puck 166 may perform chucking operations, e.g., vacuum chucking, electrostatic chucking, etc. Substrate support assembly 150 may further include a base plate, a cooling plate and/or an insulator plate (not shown).

Processing chamber 100 includes chamber body 102 and lid 104 that enclose an interior volume 106. Chamber body 102 may be fabricated from aluminum, stainless steel, or other suitable material. Chamber body 102 generally includes sidewalls 108 and a bottom 110. An outer liner 116 may be disposed adjacent to side walls 108, e.g., to protect chamber body 102. Outer liner 116 may be fabricated and/or coated with a plasma or halogen-containing gas resistant material. Outer liner 116 may be fabricated from or coated with aluminum oxide. Outer liner 116 may be fabricated from or coated with yttria, yttrium alloy, oxides thereof, etc.

Lid 104 may be supported on sidewall 108 of chamber body 102. Lid 104 may be openable, allowing access to interior volume 106. Lid 104 may provide a seal for processing chamber 100 when closed. Plasma source 158 may be coupled to processing chamber 100 to provide process, cleaning, backing, flushing, etc., gases and/or plasmas to interior volume 106 through gas distribution assembly 130. Gas distribution assembly 130 may be integrated with lid 104.

Examples of processing gases that may be used in processing chamber 100 include halogen-containing gases, such as C₂F₆, SF₆, SiCl₄, HBr, NF₃, CF₄, CHF₃, CH₂F₃, Cl₂ and SiF₄. Other reactive gases may include O₂ or N₂O. Non-reactive gases may be used for flushing or as carrier gases, such as N₂, He, Ar, etc. Gas distribution assembly 130 (e.g., showerhead) may include multiple apertures 132 on the downstream surface of gas distribution assembly 130. Apertures 132 may direct gas flow to the surface of substrate 144. In some embodiments, gas distribution assembly may include a nozzle (not pictured) extended through a hold in lid 104. A seal may be made between the nozzle and lid 104. Gas distribution assembly 130 may be fabricated and/or coated by a ceramic material, such as silicon carbide, yttrium oxide, etc., to provide resistance to processing conditions of processing chamber 100.

Substrate support assembly 150 is disposed in interior volume 106 of processing chamber 100 below gas distribution assembly 130. Substrate support assembly 150 holds a substrate 144 during processing. An inner liner (not shown) may be coated on the periphery of substrate support assembly 148. The inner liner 118 may share features (e.g., materials of manufacture, function, etc.) with outer liner 116.

Substrate support assembly 150 may include supporting pedestal 152, insulator plate, base plate, cooling plate, and puck 166. Puck 166 may include electrodes 536 for providing one or more functions. Electrodes may include chucking electrodes (e.g., for securing substrate 144 to an upper surface of puck 166), heating electrodes, RF electrodes for plasma control, etc.

Protective ring 146 (e.g. a process kit ring, an insert ring, and/or a support ring) may be disposed over a portion of puck 166 at an outer perimeter of puck 166. Puck 166 may be coated with a protective layer (not shown). Protective layer 136 may be a ceramic such as Y₂O₃ (yttria or yttrium oxide), Y₄Al₂O₉ (YAM), Al₂O₃(alumina), Y₃Al₅O₁₂ (YAG), YAlO₃ (YAP), quartz, SiC (silicon carbide), Si₃N₄ (silicon nitride), Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stablized ZrO₂ (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

Puck 166 may further include multiple gas passages such as grooves, mesas, and other features that may be formed in an upper surface of puck 166. Gas passages may be fluidly coupled to a gas source 105. The gas outlet 105 further delivers SiO₂, H₂, or a combination thereof. Gas from gas source 105 may be utilized as a heat transfer or backside gas, may be utilized for control of one or more lift pins of puck 166, etc. Multiple gas sources may be utilized (not shown). Gas passages may provide a gas flow path for a backside gas such as He via holes drilled in puck 166. Backside gas may be provided at a controlled pressure into gas passages to enhance heat transfer between puck 166 and substrate 144.

Puck 166 may include one or more clamping electrodes. The clamping electrodes may be controlled by chucking power source 182. Clamping electrodes may further couple to one or more RF power sources through a matching circuit for maintaining a plasma formed from process and/or other gases within processing chamber 100. The RF power sources may be capable of producing an RF signal having a frequency from about 50 kilohertz (kHz) to about 3 gigahertz (GHz) and a power of up to about 10,000 Watts. Heating electrodes of puck 166 may be coupled to heater power source 178.

An exhaust line 126 may connected to chamber body 102, and may couple interior volume 106 to a pump system 128 and/or to a recirculation system 151. Pump system 128 may include one or more pumps, valves, lines, manifolds, tanks, etc., utilized to evacuate and regulate the pressure of interior volume 106. Exhaust line 126 may include a valve that may direct gases to pump system 128 and/or to a filter 194. The filter 194 may be connected to pump system 128 and/or to recirculation system 151.

In embodiments, a second sensor 198 may be coupled to the exhaust line 126. The second sensor 198 may be connected to the exhaust line 126 upstream of the filter 194 to measure the concentration of one or more gases in an exhaust from processing chamber 101. In one embodiment, second sensor 198 is configured to measure a concentration of one or more silicon-containing species in the exhaust. In one embodiment, second sensor 198 is configured to measure an amount of SiF₄ in the exhaust. In one embodiment, second sensor is configured to measure at least one of NF₃ or fluorine radicals in the exhaust. In some embodiments, second sensor 198 is connected to controller 188 to provide sensor measurements to controller 188. Based on sensor measurements from second sensor 198, controller 188 may determine an amount of silicon that is being removed from an interior of processing chamber 101. A silicon-containing film may build up on exposed surfaces of the interior volume 106 of processing chamber during deposition processes in embodiments. Cleaning processes may periodically be performed to remove the buildup of silicon-containing film. As the film is reduced, the amount of silicon-containing species in the exhaust may also be reduced. This information may be used by controller 188 to determine how close a clean process is to complete and/or whether a clean process is complete. For example, if no silicon-containing species are detected, then controller 188 may determine that a clean process is complete. If a reduced amount of silicon-containing species is detected (e.g., an amount less than a threshold), then controller 188 may determine that a clean process is close to complete. This may prompt controller 188 to adjust a clean process (e.g., by reducing an amount of fluorine-containing gas (e.g., NF₃) to plasma source, by reducing a plasma power, by reducing a plasma frequency, etc.). This may reduce a chance that the process chamber 101 is exposed to more fluorine-based plasma after cleaning is complete.

In embodiments, manufacturing system 100 includes recirculation system 151, which recirculates at least a portion of the exhaust from processing chamber 101 back to plasma source 158. Fluorine-containing gases may be expensive, and may also be substantial greenhouse gases. Accordingly, it is beneficial in embodiments to reduce an amount of fluorine-based gases that are used in processes such as plasma-based processes. Often not all of the fluorine (or other active species) in a plasma get used. As a result, the exhaust from processing chamber 101 may contain useful gases that could be reused. Reuse of such useful gases (e.g., F₂, Ar, etc.) may reduce an amount of gases that are supplied to plasma source 158 from gas panel 192. Accordingly, recirculation system 151 recirculates some gases in exhaust back to plasma source 158 in embodiments.

In embodiments, there are some gases in exhaust from processing chamber 101 that could be harmful to plasma source 158 and/or that are not useful. Accordingly, in some embodiments a filter 194 is disposed between exhaust line 126 and recirculation line 151. Filter 194 may filter out gases that might be harmful to plasma source 158 and/or that may not be useful, and may allow useful gases such as Ar and F₂ to pass through. Filtered out gases may be sent to pump system 128, while target gases such as Ar and/or F₂ may pass through filter 194 to recirculation system 151.

Pump system 128 may output exhaust gases that have not been provided to recirculation system 151 to an abatement system 196. Abatement system 196 may dispose of the output gases, such as by burning the output gases in the exhaust.

In some embodiments, the filter 194 is a pressure swing adsorption (PSA) bed filter. PSA is a technology that may be used in gas separation and purification processes. Pressure Swing Adsorption operates by using adsorbent materials (typically, porous substances like zeolites or activated carbon) in a bed through which a gas mixture (e.g., in the exhaust) is passed. Different gas components are adsorbed by the material at different pressures, and by altering the pressure, specific gases can be selectively released and collected. PSA may include the steps of adsorption, depressurization, and purge. The adsorption step includes exposing the gas mixture to a high pressure, at which a target gas component or components adhere(s) to the surface of the adsorbent material, and other gases may be pumped out to pump system 128. In a depressurization step, the pressure in the PSA bed filter is reduced, releasing the adhered gas, which may flow to recirculation system 151. In a purge step, another gas may be used to purge the adsorbent bed, removing any residual undesired gases and sending them to pump system 128 and preparing the bed for a next cycle. In embodiments, the PSA bed is configured to adsorb F₂. In one embodiment, filter 194 includes multiple PSA bed filters to ensure continuous operation. Accordingly, ne bed can be in the adsorption phase while another is being regenerated (through desorption and purging).

In one embodiment, filter 194 may include pellets that adsorb SiF₄. These pellets may be refurbished and/or replaced after the adsorbing potential has deteriorated over prolonged use. In some embodiments. The filter 194 adsorbs at least one of HF, SiF₄, NF, NF₂, NF₃ N₂, or O₂.

In embodiments, the filter 194 may direct excess SiF₄, HF, or any other non-target gases to a pump 128. In some embodiments, the pump 128 may direct the flow of filtered materials to abatement system 196.

In embodiments, the one or more first compounds that are filtered out by filter 194 include at least one of SiF₄ or HF, and the one or more second compounds that are separated out from the exhaust and sent to recirculation system 151 include at least one of the fluorine or argon.

In some embodiments, a third sensor 197 (e.g., a gas sensor) may be connected to recirculation system 151 to detect a concentration of one or more gases in the recirculation line. The third sensor 197 may be configured to detect and measure at least one of F₂, SiF₄, HF, Ar, N₂, or O₂. The third sensor 197 may determine a concentration of F₂ that is being provided back to plasma source 158 in embodiments. Controller 188 may control an amount of fluorine that is provided to plasma source 158 in embodiments. Controller 188 may receive measurements from third sensor 197 to determine an amount of fluorine that is delivered to plasma source 158 from recirculation system 151. Controller 188 may determine a target amount of fluorine to be delivered to plasma source 158, and may subtract the amount of fluorine provided by recirculation system 151 from the target amount of fluorine. A remaining difference in amount of fluorine may be provided by a fluorine-rich gas (e.g., NF₃) from gas panel 192. Accordingly, controller 192 may reduce an amount of NF₃ or other fluorine-containing gas delivered to plasma source 158 from gas panel 192 based on the data from third sensor 197 in embodiments.

In some embodiments, argon plasma may be maintained in the processing chamber 101 to keep particles suspended and prevent deposition on chamber processing surfaces. In embodiments, a cleaning process may generate silicon nitride in the process chamber 101 that is additionally filtered out and removed. In some embodiments, the filter 194 may be configured to receive an exhaust from the processing chamber 101 via the exhaust line 126. The filter 194 may filter out one or more first compounds from the exhaust and provide a filtered exhaust that includes one or more second compounds to the recirculation controller 192, one or more of which may be measured by third sensor 197 and reported to controller 188. In embodiments, the third sensor 197 downstream of the filter 194 measures the concentration of the fluorine radicals in the filtered exhaust. In some embodiments, the controller 188 may further adjust the one or more settings of at least one of the RPS 158 or the processing chamber 101 based on the measured concentration of the at least one of NF₃ of the fluorine radicals in the exhaust, such as described above.

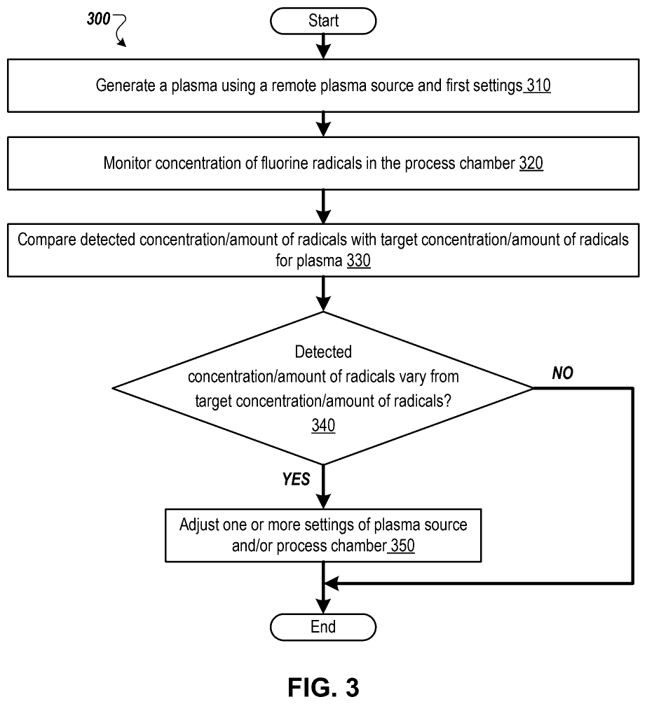

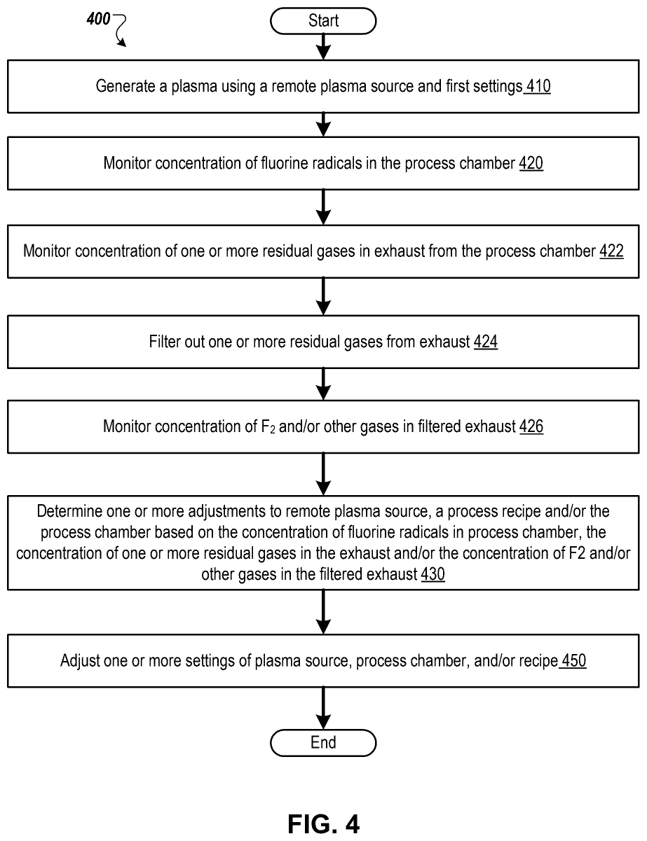

As touched on above, controller 188 (also referred to as a system controller) may control one or more parameters and/or set points of the plasma source 158 and/or processing chamber 101. Controller 188 can be and/or include a computing device such as a personal computer, a server computer, a programmable logic controller (PLC), a microcontroller, and so on. Controller 188 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. Controller 188 can include a data storage device (e.g., one or more disk drives and/or solid state drives), a main memory, a static memory, a network interface, and/or other components. Controller 188 can execute instructions to perform any one or more of the methodologies and/or embodiments described herein. The instructions can be stored on a computer readable storage medium, which can include the main memory, static memory, secondary storage and/or processing device (during execution of the instructions). In embodiments, execution of the instructions by controller 188 causes controller 188 to perform the methods of FIGS. 3 and 4. For example, controller 188 may receive measurements from radical sensor 135 indicating a concentration of a particular species of radicals in a received or generated plasma, may receive measurements from second sensor 198 indicating a concentration of one or more byproduct species that result from the radicals interacting with a surfaces in processing chamber, and/or may receive measurements from third sensor 197 indicating a concentration of one or more target gases to be recirculated back to plasma source 158. Controller 188 may adjust one or more properties or settings (e.g., such as a plasma power, flow rate of one or more gases to plasma source, etc.) of plasma source 158 responsive to the measured radical concentration, the measured byproduct concentration and/or the measured concentration of target gases recirculated to plasma source 158. Controller 188 may additionally adjust one or more properties of processing chamber 101, such as pressure. Controller 188 can also be configured to permit entry and display of data, operating commands, and the like by a human operator.

FIGS. 2A-2D illustrate embodiments of a sensor for detecting radicals of a target gas species, in accordance with embodiments of the present disclosure. FIG. 2A is a sectional side view of a radical sensor, according to some embodiments. FIG. 2B is a back view of the radical sensor of FIG. 2A, according to some embodiments. FIG. 2C is a front view of the radical sensor of FIG. 2A, according to some embodiments.

In embodiments, the radical sensor comprises a QCM sensor base. A piece of solid material of any shape can normally oscillate at certain resonant frequencies. By increasing the mass of the vibrating unit, the typical result is the decrease of that solid material's resonant frequencies. This is the basic principle of a QCM.

The QCM sensor base may include a thin plate of quartz crystal that oscillates in the thickness-shear mode because such a QCM sensor base has high sensitivity to mass change on the crystal. The piezoelectric nature of quartz crystal allows the crystal to be driven into oscillation and with its resonant frequency measured by simple electrical means. In embodiments, the quartz crystal is precisely cut at certain angles with respect to its crystallographic axes. In embodiments, the quartz crystal is an AT-cut quartz crystal.

As shown in FIGS. 2A-C, the radical sensor 200 includes a quartz crystal base 215, which may have a flat face and a convex face. The flat face may be a front face and the convex face may be a back face. The flat face may be covered by a front electrode 230. The convex face may be covered by a back electrode that includes a back electrode edge 225 connected to a back electrode center 220 via one or more electrode bridges 227. This configuration enables an alternating current to be applied to and/or read from the electrodes without compromising the ability of the quartz body 215 to oscillate freely. A sensing surface of the QCM may be a center region of the front face (e.g., a center region of front electrode 230). In embodiments, the sensing surface of the QCM is coated with a film 235 that is sensitive to reaction with a particular molecular species of a target gas species (e.g., fluorine radicals). The composition of the film 235 may depend on the application for which the radical sensor 200 will be used.

In some embodiments, the film 235 is composed of a material that reacts with a radical molecular species of a target gas, but that does not react to stable molecular species of the target gas. For example, the material may react to fluorine radicals, but may not react to stable molecules containing fluorine (e.g., F₂, C₂F₆, SF₆, NF₃, CF₄, CHF₃, CH₂F₃, etc.). The material may also not react to other molecules that may be included in a gas flow, whether those other molecules are radicals or stable molecular species. For example, the material may react to fluorine radicals, but may not react to carbon radicals, nitrogen radicals, hydrogen radicals, etc. Alternatively, the material may only react to hydrogen radicals, or may only react to carbon radicals, or may only react to some other radicals.

In one embodiment in which the radical sensor is tuned to detect fluorine radicals, the film or coating 235 comprises silicon dioxide (SiO₂), tungsten, or a tungsten oxide (e.g., tungsten (III) oxide or W₂O₃) and/or organic materials (such as photoresist). In one embodiment in which the radical sensor is tuned to detect fluorine radicals, the film or coating 235 comprises a transition metal that selectively reacts with fluorine radicals. In one embodiment in which the radical sensor is tuned to detect hydrogen radicals, the film or coating 235 comprises a polymer of carbon and hydrogen. One example of a polymer that may be used is polymethyl methacrylate (PMMA). In one embodiment in which the radical sensor is tuned to detect nitrogen radicals, the film or coating 235 comprises a fluorinated polymer. In embodiments, the target radicals react with the film 235 to form a gas, which consumes some portion of the film 235. The consumption of some portion of the film 235 reduces the number of molecules of the film 235, and thus reduces an overall mass of the film. This reduction in mass may be detected by the QCM sensor on which the film 235 has been formed.

In one embodiment, the film 235 has a thickness of about 1-100 microns. In one embodiment, the film 235 has a thickness of about 30-40 microns. Other thicknesses, such as 10, 20, 30, 40, 50, 60, 70, 80 or 90 microns may also be used for the film 235.

The QCM sensor base including the crystal 215 and electrodes 220, 225, 230 measures the Areal Mass Density (mass per unit area) of a material which uniformly covers the sensitive area on the sensing crystal. For heavy loading on the crystal 215, its accuracy depends on the knowledge of the shear-mode acoustic impedance value of the deposited material. Larger crystals do not have higher sensitivity. The QCM is not a weighing device because it does not require a gravitational force. It can be used in space with zero gravity. In embodiments, a thickness reading t_{f} may be derived from the areal mass density value, which is equivalent to t_{f}ρ_{f}, by using the density of the film ρ_{f}. The entry of a wrong density value results a wrong thickness reading. The areal mass density measurement is in absolute value in embodiments. In embodiments, no calibration is needed for a properly designed QCM. Temperature variation, stress, gas adsorption and desorption, surface reaction, etc. can all give false signals.

The QCM can measure mass on a sensing surface of the QCM according to the equation

$$\frac{m}{A} ∝ ρ {t}^{n} ,$$

where m/A is mass per unit area, ρ is density of a material on a sensing surface of the QCM, t is thickness and n a constant (≥0) where for linear dependence n is equal to 1. In embodiments, the sensitivity of QCM can be down to better than 1×10⁻⁹ g/cm². In terms of thickness for a material, say, Al, with density ρ=2.7 g/cm³, this QCM sensitivity is equivalent to 0.1 Å of Al. Thickness change expressed in terms of mass per unit area, or areal mass density, is more appropriate at subatomic sizes.

A piezoelectric resonator can be represented by a simple equivalent circuit for electrical analysis, as shown in FIG. 2E. The mechanical behavior of a quartz crystal resonator (e.g., QCM) can be represented by an electrical equivalent model as shown. This is the so-called the Butterworth van Dyke (BVD) electrical model of a quartz crystal resonator. In the motional arm (the upper branch) of the BVD model, it consists of three components that determine the series resonance frequency of the quartz crystal plate. Rₐ corresponds to the energy dissipation due to mechanical coupling between the crystal and its holder. For QCM applications, added mass load on the crystal surface also causes Rₐ to increase. Lₐ corresponds to the mass being displaced during oscillation. For QCM applications, the total mass includes that of the crystal, the electrodes, and the deposited thin film materials. Cₐ corresponds to the stored energy in the oscillator that is related to the elastic properties of quartz, electrodes, and the deposited materials. The parasitic capacitance C₀ represents the total static capacitances of the crystal electrodes, the holder, and the connecting cable.

FIG. 2D is a sectional side view of the radical sensor of FIG. 2A with the addition of a charged grating or grid, according to some embodiments. The radical sensor 200 shown in FIGS. 2A-2C in embodiments measures all radicals without respect to charge. In some embodiments, it may be advantageous to measure only neutral radicals or only radicals having a particular charge. In order to measure only neutral radicals of a particular molecular species, a charged grating or grid 252 may be disposed in front of the front face of the radical sensor 200. The charged grating or grid 252 may include a stack of meshes (e.g., wire meshes) that have particular charge. In one embodiment, as shown, a first grating or mesh is positively charged, a second grating or mesh may be grounded, and a third grating or mesh may be negatively charged. The positively charged mesh or grating may repel positively charged molecules or ions and the negatively charged mesh or grating may repel negatively charged molecules or ions. As a result, the only molecules that reach the film 235 may be neutral molecules. Of the neutral molecules that reach the film 235, only the radicals of a particular gas species may actually react with the film 235.

In one embodiment, in order to measure an amount of positively and/or negatively charged radicals, a pair of radical sensors may be used. A first radical sensor may include the charged gratings or grids, and a second radical sensor may not include the charged gratings or grids. All radicals of a target gas species may be detected by the second radical sensor, and only neutral radicals of the target gas species may be detected by the first radical sensor. A difference between the measurements of the two radical sensors may then be computed to determine an amount of the radicals detected by the second radical sensor that were attributable to charged radicals. The grating may be modified to only filter out positively charged molecules/ions or to only filter out negatively charged molecules. Accordingly, by combining two or more radical sensors, each with a different grating configuration (e.g., one not including any grating), an amount of positively charged radicals may be detected, an amount of negatively charged radicals may be detected, and/or an amount of neutral radicals may be detected.

FIG. 2F shows an expanded view of one example of a radical sensor included in a sensor holder. As shown, a cover compresses a quartz crystal (e.g., having the form shown in FIGS. 2A-D, with a coating that is reactive only to a specific radical species on a sensing surface) against a spring contact. An aperture exposes the sensing surface that includes the coating. Many other different configurations of sensor holders may also be used, such as is shown in FIGS. 2G and 2H.

FIG. 3 is a flow chart of one embodiment for a method 300 of controlling a plasma source using a radical sensor. At block 310 of method 300, a remote plasma source generates a plasma using first settings. The plasma may be generated by a remote plasma source (e.g., a plasma source external to a process chamber) or by a local plasma source (e.g., a plasma source internal to a process chamber). At block 320, a first radical sensor (e.g., as described hereinabove) is used to detect a concentration/amount of radicals in the plasma. The concentration of fluorine radicals in the plasma directly related to the rate of the process of the processing chamber (e.g. etching, deposition, etc.). The radicals of a target gas species may react with a coating on the radical sensor, causing a mass on a sensing surface of the radical sensor to change. The density and/or mass of the coating may be known, and a change in the mass of the coating may be detected based on a change in the resonant frequency of an oscillating piezoelectric material (e.g., QCM) of the radical sensor. This change in mass together with knowledge about the mass of the materials that make up the coating may be used to determine a number of radicals that reacted with the coating, and thus the concentration and/or amount of radicals in the gas flow.

At block 330, processing logic compares the detected concentration/amount of radicals of the target gas species to a target concentration/amount of radicals for the plasma. At block 340, processing logic determines whether the detected concentration/amount of radicals of the target gas species varies from the target concentration/amount by more than a concentration threshold amount (e.g., if a difference between the target concentration and the detected concentration is more than a difference threshold). If the difference exceeds a difference threshold, the method continues to block 350 and one or more settings of the plasma source may be adjusted. The one or more settings may include pressure flow of excited gases to the processing chamber, frequency of the remote plasma source, or power supplied to the remote plasma source. For example, the plasma power may be increased to increase the amount of radicals that are included in the plasma or may be decreased to reduce an amount of radicals that are included in the plasma. If the difference is less than the difference threshold, then the method may end.

In some embodiments the plasma may include Ar, N₂, or O₂. The plasma may further include Ar, N₂, or O₂ and fluorine radicals that include HF, SiF₄, NF₃, F₂, NF, NF₂, or a combination thereof.

FIG. 4 is a flow chart of one embodiment for a method 400 of controlling fluorine radicals concentration in a plasma via a remote plasma source, a radical sensor, and recycled filtered process exhaust. At block 410 of method 400, a remote plasma source generates a plasma using first settings. The plasma may be generated by a remote plasma source (e.g., a plasma source external to a process chamber) or by a local plasma source (e.g., a plasma source internal to a process chamber). At block 420, a first radical sensor (e.g., as described hereinabove) is used to detect a concentration/amount of radicals in the plasma. The radicals of a target gas species may react with a coating on the radical sensor, causing a mass on a sensing surface of the radical sensor to change. The density and/or mass of the coating may be known, and a change in the mass of the coating may be detected based on a change in the resonant frequency of an oscillating piezoelectric material (e.g., QCM) of the radical sensor. This change in mass together with knowledge about the mass of the materials that make up the coating may be used to determine a number of radicals that reacted with the coating, and thus the concentration and/or amount of radicals in the gas flow.

At block 422, a second sensor may be used to detect a concentration/amount of one or more residual gases in the exhaust from the process chamber. The residual gases may include a byproduct, such as SiF₄, which may be measured. In response to the detection of a concentration of residual gas in an exhaust from the processing chamber, one more of the settings of at least one of the remote plasma source or the processing chamber may be adjusted.

At block 424, the residual gases in the exhaust from the process chamber are passed through an adsorbent bed filter to filter out one or more of the residual gases. At block 426, the concentration of F₂ and/or other gases are monitored in the filtered exhaust via a third sensor.

At block 430, processing logic receives the detected concentration/amount of radicals of the target gas species, the concentration of one or more residual byproduct gases in the exhaust, and/or the concentration of one or more target gases in the filtered exhaust. Processing logic may then determine one or more adjustments to the remote plasma source, a process recipe and/or the processing chamber based on one or more of the measured concentrations. For example, processing logic may determine a target amount of fluorine to provide to the plasma source based on the detected fluorine concentration. Processing logic may further determine how much fluorine is being provided to the plasma source from the recirculated and filtered exhaust, and based on that information and the target amount of fluorine may determine an amount of a fluorine-containing process gas (e.g., NF₃) to provide to the plasma source. In another example, processing logic may determine when to adjust and/or stop a cleaning process based on an amount of a silicon-containing byproduct detected by the second sensor. For example, if the amount of silicon-containing byproduct drops below a threshold, then processing logic may reduce an amount of fluorine provided to the plasma source, may reduce a plasma power, and so on. If the amount of silicon-containing byproduct reaches zero (or is close to zero), processing logic may determine to stop a cleaning process.

In an example, processing logic determines an amount of NF₃ delivered to the plasma source and an amount of F₂ detected by the third sensor that is recirculated to the plasma source, and determines a ratio of the F₂ to the NF₃. Processing logic may adjust a power of the plasma source based on the ratio of F₂ to NF₃. Higher power is generally used to break F₂ into fluorine radicals than is used to break NF₃ into fluorine radicals. Accordingly, as the ratio of F₂ to NF₃ increases, processing logic may increase a power of the plasma source to achieve a target amount of fluorine radicals. As the amount of F₂ goes down relative to the amount of NF₃, the power to the plasma source may be decreased to maintain the target concentration of fluorine radicals.

One or more settings of the plasma source and/or processing chamber that may be adjusted by processing logic may include flow rate of one or more gases to the plasma source, flow rate of excited gases to the processing chamber, frequency of the remote plasma source, power supplied to the remote plasma source, and so on. For example, the plasma power may be increased to increase the amount of radicals that are included in the plasma or may be decreased to reduce an amount of radicals that are included in the plasma.

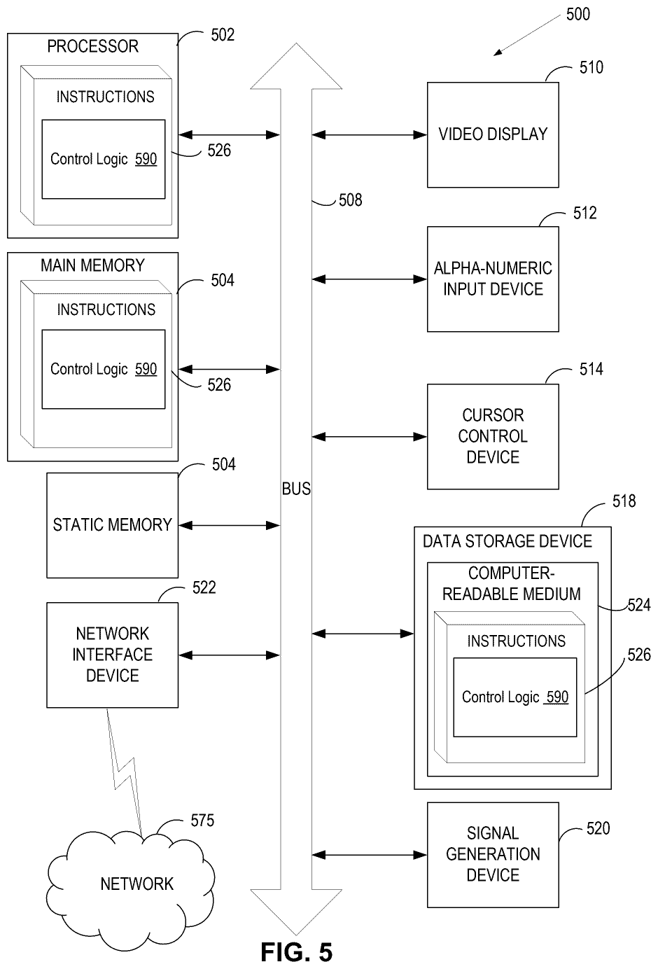

FIG. 5 is a block diagram illustrating a computer system 500, according to some embodiments. In some embodiments, computer system 500 corresponds to controller 188 of FIG. 1. In some embodiments, computer system 500 may be connected (e.g., via a network, such as a Local Area Network (LAN), an intranet, an extranet, or the Internet) to other computer systems. The term “computer” shall include any collection of computers that individually or jointly execute a set (or multiple sets) of instructions to perform any one or more of the methods described herein.

In a further aspect, the computer system 500 may include a processing device 502, a volatile memory 504 (e.g., Random Access Memory (RAM)), a non-volatile memory 506 (e.g., Read-Only Memory (ROM) or Electrically-Erasable Programmable ROM (EEPROM)), and a data storage device 518, which may communicate with each other via a bus 508.

Processing device 502 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 500 may further include a network interface device 522 (e.g., coupled to network 574). Computer system 500 also may include a video display unit 510 (e.g., an LCD), an alphanumeric input device 512 (e.g., a keyboard), a cursor control device 514 (e.g., a mouse), and a signal generation device 520.

In some embodiments, data storage device 518 may include a non-transitory computer-readable storage medium 524 (e.g., non-transitory machine-readable medium) on which may store instructions 526 encoding any one or more of the methods or functions described herein, including instructions for control logic 590 that may monitor concentrations of gases, radicals, etc., and determine changes to process chambers and/or remote plasma sources based on detected concentrations.

Instructions 526 may also reside, completely or partially, within volatile memory 504 and/or within processing device 502 during execution thereof by computer system 500, hence, volatile memory 504 and processing device 502 may also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A system comprising:
a remote plasma source;
a processing chamber comprising a radical sensor, wherein the radical sensor is configured to measure a concentration of fluorine radicals in the processing chamber; and
a controller to adjust one or more settings of at least one of the remote plasma source or the processing chamber based on the measured concentration of fluorine radicals in the processing chamber.

2. The system of claim 1, further comprising:
a gas panel configured to deliver at least one gas to the remote plasma source, wherein the at least one gas comprises NF₃, F₂, C₂F₆, SF₆, SiCl₄, HBr, NF₃, CF₄, CHF₃, CH₂F₃, Cl₂ and SiF₄, Ar, N₂, He, or a combination thereof.

3. The system of claim 1, wherein the remote plasma source comprises a power source connected to deliver plasma-generating power to an energy conduit and a gas distribution assembly connected to a gas outlet for delivering excited gases to the processing chamber, and wherein the one or more settings of the remote plasma source comprise a power output by the power source.

4. The system of claim 3, wherein the excited gases comprise the fluorine radicals.

5. The system of claim 4, wherein the gas outlet further delivers SiO₂, H₂, or a combination thereof.

6. The system of claim 4, wherein the fluorine radicals comprise NF₃, F₂, NF, NF₂, or a combination thereof.

7. The system of claim 1, wherein the one or more settings of at least one of the remote plasma source or the processing chamber comprise at least one of a pressure within the processing chamber, a flow of excited gases to the processing chamber, a power of the remote plasma source, or a frequency of the remote plasma source.

8. The system of claim 1, further comprising:
an exhaust line connected to the processing chamber;
a recirculation line connected to an input of the remote plasma source; and
a filter coupled to the exhaust line and to the recirculation line, wherein the filter is configured to receive an exhaust from the processing chamber via the exhaust line, filter out one or more first compounds from the exhaust, and provide filtered exhaust comprising one or more second compounds to the recirculation line.

9. The system of claim 8, wherein the one or more first compounds comprise at least one of SiF₄ or HF, and wherein the one or more second compounds comprise at least one of the fluorine radicals or Ar.

10. The system of claim 8, wherein the filter comprises a pressure swing adsorption bed.

11. The system of claim 8, further comprising:
a second sensor in the recirculation line downstream of the filter to measure a concentration of the fluorine radicals in the filtered exhaust;
wherein the controller is further to adjust the one or more settings of at least one of the remote plasma source or the processing chamber based on the measured concentration of at least one of NF₃ or the fluorine radicals in the exhaust.

12. The system of claim 1, further comprising:
an exhaust line connected to the processing chamber to receive an exhaust from the processing chamber during a clean process; and
a second sensor in the exhaust line to measure a concentration of at least SiF₄ in the exhaust during the clean process;
wherein the controller is further to determine when to stop the clean process based at least in part on the concentration of at least the SiF₄ in the exhaust.

13. A method comprising:
generating a plasma using a remote plasma source, the plasma comprising fluorine radicals;
monitoring a concentration of the fluorine radicals in a processing chamber using a radical sensor; and
adjusting one or more settings of at least one of the remote plasma source or the processing chamber based at least in part on concentration of the fluorine radicals in the processing chamber.

14. The method of claim 13, wherein the one or more settings comprise at least one of pressure, flow of excited gases to the processing chamber, a power setting of the remote plasma source or a frequency setting of the remote plasma source.

15. The method of claim 13, further comprising:
detecting a concentration of a residual gas in an exhaust from the processing chamber; and
adjusting the one or more settings of at least one of the remote plasma source or the processing chamber based on a ratio of the concentration of the fluorine radicals to the concentration of the residual gas.

16. The method of claim 13, further comprising:
determining that the concentration of the fluorine radicals is higher than a concentration threshold; and
responsive to determining that the concentration of the fluorine radicals is higher than the concentration threshold, adjusting the one or more settings of at least one of the remote plasma source or the processing chamber.

17. The method of claim 13, further comprising:
recirculating at least a portion of exhaust from the processing chamber to the remote plasma source.

18. The method of claim 17, further comprising:
adsorbing one or more residual gases in the exhaust from the processing chamber prior to recirculating at least the portion of the exhaust to the remote plasma source, wherein F₂ is recirculated to the remote plasma source.

19. A system, comprising:
a remote plasma source;
a processing chamber comprising a radical sensor, wherein the radical sensor is configured to measure a concentration of fluorine radicals in the processing chamber;
an exhaust line connected to the processing chamber, the exhaust line comprising a second sensor to measure a concentration of one or more gases in the exhaust line;
a recirculation line connected to an input of the remote plasma source, the recirculation line comprising a third sensor to measure a concentration of one or more additional gases in the recirculation line;
a filter coupled to the exhaust line and to the recirculation line, wherein the filter is configured to receive an exhaust from the processing chamber via the exhaust line, filter out one or more first compounds from the exhaust, and provide filtered exhaust comprising one or more second compounds to the recirculation line; and
a controller to adjust one or more settings of at least one of the remote plasma source or the processing chamber based on at least one of the measured concentration of fluorine radicals in the processing chamber, a measurement of the second sensor, or a measurement of the third sensor.

20. The system of claim 19, wherein the one or more gases comprise a silicon-containing byproduct, and wherein the one or more additional gases comprise at least one of fluorine or argon.
